(19) United States
(12) Patent Application Publication
(10) Pub. No.: US 2010/0283056 A1
(43) Pub. Date: Nov. 11, 2010

(54) DISPLAY APPARATUS, LIQUID CRYSTAL DISPLAY APPARATUS, ORGANIC EL DISPLAY APPARATUS, THIN-FILM SUBSTRATE, AND METHOD FOR MANUFACTURING DISPLAY APPARATUS

(76) Inventor: Takuto Yasumatsu, , Osaka (JP)

Correspondence Address: BIRCH STEWART KOLASCH & BIRCH, PO BOX 747, FALLS CHURCH, VA, 22040-0747, US

(21) Appl. No.: 12/746,072

(22) PCT Filed: Oct. 16, 2008
(86) PCT No.: PCT/JP2008/002939

§ 371 Date: Jun. 3, 2010

(30) Foreign Application Priority Data
Mar. 6, 2008 (JP) 2008-056768

(51) Int. Cl. H01L 33/16; H01L 21/04

(52) U.S. Cl. 257/59; 257/72; 438/34; 257/E33.053; 257/E21.04

(57) ABSTRACT

A liquid crystal display apparatus (10) includes a first substrate (20) including a base layer (71) and a display element layer formed on the base layer (71). The base layer (71) of the first substrate (20) is constituted by a transparent and colorless resin film formed by vapor deposition at room temperature.

### TECHNICAL FIELD

The present invention relates to a display apparatus, a thin-film substrate, and a method for manufacturing the display apparatus.

### BACKGROUND ART

Recently, flexible substrates using plastic substrates etc., which are more advantageous than glass substrates in flexibility, impact resistance, and lightweight properties, have received considerable attention in the field of displays, and have potential to develop new types of displays which were impossible to realize in displays including the glass substrates.

When a thin-film device such as the flexible substrate is formed, a technique has been devised, in which a thin-film device is formed on a separately-prepared support substrate, and such a thin-film device is transferred to a desired substrate.

Such a technique is disclosed in, e.g., Patent Document 1. According to Patent Document 1, a first separation layer constituted by a hydrogen-containing amorphous silicon film is formed on a first base material in a first process, followed by forming a thin-film device layer on the first separation layer in a second process. Next, a second base material is bonded to the thin-film device layer in a third process. Subsequently, the first separation layer is irradiated with laser light for phase transition from the amorphous silicon film to a polysilicon film, and for generation of hydrogen gas. Then, detachment is caused in the first separation layer to detach the first base material, thereby preparing a thin-film device.

### CITATION LIST

### Patent Document

PATENT DOCUMENT 1: Japanese Patent Publication No. 2001-51296

### SUMMARY OF THE INVENTION

A display apparatus of the present invention includes a first substrate including a base layer, and a display element layer formed on the base layer, and the base layer of the first substrate is constituted by a transparent and colorless resin film formed by vapor deposition at room temperature.

The display apparatus of the present invention may further includes a second substrate including a base layer provided so as to face the first substrate, and constituted by a transparent and colorless resin film, and a display element layer formed on the base layer.

In the display apparatus of the present invention, a sacrificial film made of resin material having a heat-resistant temperature equal to or higher than 150° C., and a coefficient of thermal expansion equal to or less than 10 ppm/° C. may be formed corresponding to a non-display region of the display element layer between the display element layer and the base layer.

In the display apparatus of the present invention, the display element layer may include a plurality of sub-pixel regions, and a light blocking region provided so as to divide the sub-pixel regions; and a non-display region of the display element layer corresponding to the sacrificial film may be the light blocking region.

In the display apparatus of the present invention, the display element layer may include a peripheral circuit region; and a non-display region of the display element layer corresponding to the sacrificial film may be the peripheral circuit region.

In the display apparatus of the present invention, the sacrificial film may be made of polyimide resin.

In the display apparatus of the present invention, the transparent and colorless resin film may be made of polyparaxylene resin.

The display apparatus of claim 1 may further include an element-layer protective film is formed between the base layer and the display element layer.

In the display apparatus of the present invention, the base layer may be formed to have a thickness in which curvature or warpage of the display apparatus can be controlled.

A liquid crystal display apparatus of the present invention includes a thin film transistor (TFT) substrate including a base layer which is constituted by a transparent and colorless resin film formed by vapor deposition at room temperature, and a display element layer with TFTs formed on the base layer; and a color filter (CF) substrate including a base layer which faces the TFT substrate with liquid crystal material being interposed therebetween, and which is constituted by a transparent and colorless resin film formed by vapor deposition at room temperature, and a display element layer with a color filter formed on the base layer.

A bottom-emission-type organic electro luminescence (EL) display apparatus of the present invention includes a base layer constituted by a transparent and colorless resin film formed by vapor deposition at room temperature; first electrodes formed on the base layer; organic EL layers formed on the first electrodes; and a second electrode formed on the organic EL layers.

The bottom-emission-type organic EL display apparatus of the present invention may further include a sealing film which is formed on the second electrode, and which is constituted by a laminated body of resin films and inorganic films.

A thin-film substrate of the present invention includes a base layer constituted by a transparent and colorless resin film formed by vapor deposition at room temperature; and a display element layer formed on the base layer.

A method for manufacturing a display apparatus of the present invention includes a first step for preparing a support substrate on which a sacrificial film made of resin material having a heat-resistant temperature equal to or higher than 150° C., and a coefficient of thermal expansion equal to or less than 10 ppm/° C. is formed; a second step for forming an element-layer protective film on the sacrificial film; a third step for forming a display element layer on the element-layer protective film; a fourth step for removing the support substrate from the sacrificial film; a fifth step for removing the sacrificial film from the element-layer protective film; and a sixth step for forming a base layer by vapor-depositing a transparent and colorless resin film on the element-layer protective film from which the sacrificial film is removed, at room temperature.

The method of the present invention may further include a bonded substrate forming step at which the first to third steps are repeated to form two support substrates on which the display element layers are formed, followed by bonding the substrates with the display element layers facing each other. In addition, the support substrates may be removed from the sacrificial films of the bonded substrate at the fourth step; the sacrificial films may be removed from the element-layer protective films of the bonded substrate at the fifth step; and base layers may be formed by vapor-depositing transparent and colorless resin films on the protective films from which the sacrificial films are removed, at room temperature at the sixth step.

In the method of present invention, at the fifth step, the sacrificial film corresponding to the non-display region of the display element layer may be remained, and the sacrificial film corresponding to other regions may be removed.

In the method of the present invention, the display element layer may include a plurality of sub-pixel regions, and a light blocking region provided so as to divide the sub-pixel regions; and the non-display region of the display element layer corresponding to the remaining sacrificial film may be the light blocking region.

In the method of the present invention, the display element layer may include a peripheral circuit region; and the non-display region of the display element layer corresponding to the remaining sacrificial film may be the peripheral circuit region.

In the method of the present invention, at the fifth step, the sacrificial film may be removed by plasma etching.

In the method of the present invention, at the fifth step, the sacrificial film may be removed by microwave plasma etching.

In the method of the present invention, the sacrificial film may be made of polyimide resin.

In the method of the present invention, the transparent and colorless resin film may be made of polyparaxylene resin.

In the method of the present invention, at the fourth step, the support substrate may be detached and removed from the sacrificial film by laser light irradiation.

### BRIEF DESCRIPTION OF THE DRAWINGS

FIG. 1 is a plan view of a liquid crystal display apparatus of a first embodiment.

FIG. 2 is a cross-sectional view of the liquid crystal display apparatus of the first embodiment.

FIG. 3 is a cross-sectional view of a glass substrate on which an element-layer protective film is formed.

FIG. 4 is a cross-sectional view of the glass substrate on which TFTs and metal interconnects are formed.

FIG. 5 is a cross-sectional view of a glass substrate on which an element-layer protective film is formed.

FIG. 6 is a cross-sectional view of the glass substrate on which a color filter layer is formed.

FIG. 7 is a cross-sectional view of the glass substrate on which a common electrode is formed.

FIG. 8 is a cross-sectional view of the bonded glass substrates (bonded substrate).

FIG. 9 is a cross-sectional view of the bonded substrate irradiated with laser light.

FIG. 10 is a cross-sectional view of the bonded substrate from which the glass substrates are detached.

FIG. 11 is a plot of a light transmission rate of a polyimide film (a thickness of 3.5 μm).

FIG. 12 is a plot of a light transmission rate of a polyparaxylene film (a thickness of 10 μm).

FIG. 13 is a cross-sectional view of a liquid crystal display panel of a second embodiment.

FIG. 14 is a cross-sectional view of a liquid crystal display panel of a third embodiment.

FIG. 15 is a cross-sectional view of an organic EL display apparatus of a fourth embodiment.

FIG. 16 is a cross-sectional view of a glass substrate on which an element-layer protective film is formed.

FIG. 17 is a cross-sectional view of the glass substrate on which first electrodes, organic EL layers, and a second electrode are formed.

FIG. 18 is a cross-sectional view of the glass substrate on which a sealing film is formed.

FIG. 19 is a cross-sectional view of the glass substrate irradiated with laser light.

FIG. 20 is a cross-sectional view of an organic EL display apparatus on which base layers having the maximum thickness are formed as uppermost and undermost layers.

FIG. 21 is a cross-sectional view of an organic EL display apparatus on which a base layer having the maximum thickness is formed as an undermost layer.

FIG. 22 is a cross-sectional view of an organic EL display apparatus on which a base layer having the maximum thickness is formed as an uppermost layer.

### DESCRIPTION OF EMBODIMENTS

Display apparatuses of embodiments of the present invention will be described in detail hereinafter with reference to the drawings. The present invention is not limited to the embodiments described below. Liquid crystal display apparatuses and organic EL display apparatuses will be described as examples of the display apparatuses.

### First Embodiment

### Structure of Liquid Crystal Display Apparatus 10

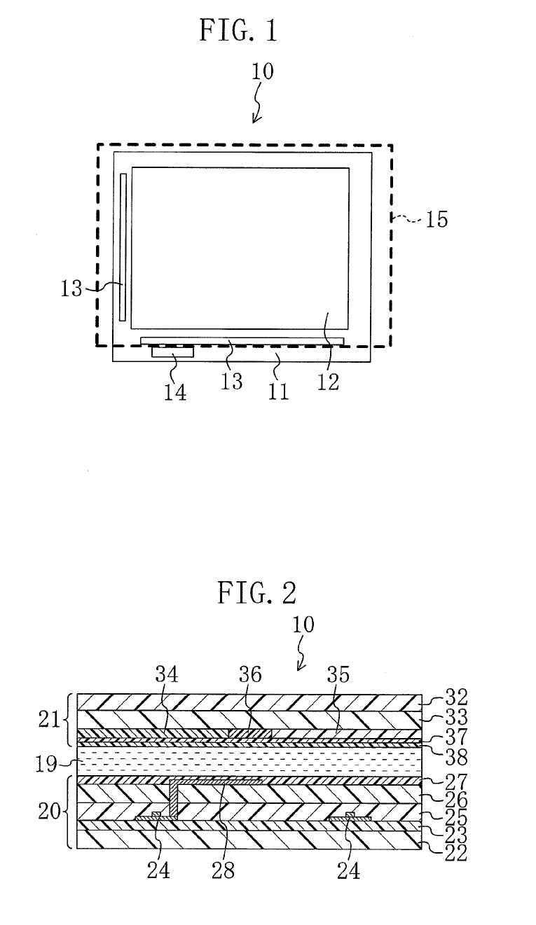

FIG. 1 is a plan view schematically illustrating a liquid crystal display apparatus 10 of a first embodiment of the present invention. FIG. 2 is a cross-sectional view schematically illustrating the liquid crystal display apparatus 10 of the first embodiment of the present invention.

The liquid crystal display apparatus 10 includes a display region 12 constituted by, e.g., a plurality of sub-pixels arranged in a matrix; and a peripheral circuit region 11 provided around the display region 12. Driver sections 13, a control section 14, etc. are provided in the peripheral circuit region 11. Application of p-Si or μ-Si TFTs realizes monolithic gate and source drivers which are equivalent to the driver sections 13. In the liquid crystal display apparatus 10, a base layer is made of, e.g., polyparaxylene resin as described below, resulting in good flexibility in, e.g., a broad region surrounded by a dotted frame 15 in FIG. 1. The flexible region is not limited to the region surrounded by the dotted frame 15 in FIG. 1, and can be formed in a desired range by controlling a film substrate structure etc.

The liquid crystal display apparatus 10 includes a liquid crystal display panel constituted by a TFT substrate 20, and a CF substrate 21 arranged so as to face the TFT substrate 20 with liquid crystal material 19 and spacers (not shown in the figure) being interposed therebetween. The liquid crystal display apparatus 10 further includes a polarizing plate, a backlight unit, etc. (not shown in the figure) attached thereto.

The TFT substrate 20 includes a base layer 22 constituted by a transparent and colorless resin film formed by vapor deposition at room temperature. As the transparent and colorless resin film constituting the base layer 22, e.g., polyparaxylene resin or acrylic resin can be used.

An element-layer protective film 23 is formed on the base layer 22. The element-layer protective film 23 is made of, e.g., SiO₂.

A display element layer including TFTs 24 etc. is formed on the element-layer protective film 23. The display element layer is constituted by the TFTs 24 formed on the element-layer protective film 23; an interlayer insulating film 25 provided so as to cover the TFTs 24; a planarized film 26 provided on the interlayer insulating film 25; metal interconnects 28 penetrating through the interlayer insulating film 25 and the planarized film 26 to be electrically connected to the TFTs 24; and an alignment film 27 provided on the planarized film 26.

The TFT 24 includes a semiconductor layer in which an active region is formed; a gate oxide film; a gate electrode; etc. The active region of the semiconductor layer is constituted by a channel region, and source and drain regions formed on both right and left sides of the channel region. The gate oxide film is formed on the channel region of the semiconductor layer. The gate electrode is formed on the gate oxide film.

The metal interconnect 28 electrically connected to the TFT 24 is made of, e.g., a transparent conductor such as indium-tin oxide (ITO) or indium-zinc oxide (IZO).

The interlayer insulating film 25 and the planarized film 26 are formed by using, e.g., a TEOS film or a SiN film.

The CF substrate 21 includes a base layer 32 constituted by a transparent and colorless resin film formed by the vapor deposition at the room temperature. As the transparent and colorless resin film constituting the base layer 32, e.g., polyparaxylene resin or acrylic resin can be used.

An element-layer protective film 33 for protecting a color filter layer at the time of manufacture, which is constituted by an inorganic film made of, e.g., SiO₂, SiON, or SiNx, is formed on the base layer 32.

The color filter film constituted by color layers 34 and 35, and a light blocking layer (black matrix) 36 is formed on the element-layer protective film 33. The light blocking layer 36 is made of metal such as chrome (Cr), or black resin. The color layers 34 and 35 have three colors of red (R), green (G), and blue (B), and the color layer having any one of the three colors is arranged in each sub-pixel of the liquid crystal display panel. A single pixel is constituted by three adjacent red, green, and blue sub-pixels, thereby displaying various colors. The light blocking layer 36 is formed so as to divide such sub-pixels.

A transparent resin layer 37 and a common electrode 38 are formed on the color filter layer. The transparent resin layer 37 is made of, e.g., acrylic resin. The common electrode 38 is made of, e.g., a transparent conductor such as ITO or IZO. A vertical alignment film (not shown in the figure) is formed on the common electrode 38.

(Manufacturing Method of Liquid Crystal Display Apparatus 10)

Next, a method for manufacturing the liquid crystal display apparatus 10 of the embodiments of the present invention will be described. The manufacturing method described below is merely an example, and the liquid crystal display apparatus 10 of the present invention is not limited to the apparatus manufactured by the method described below.

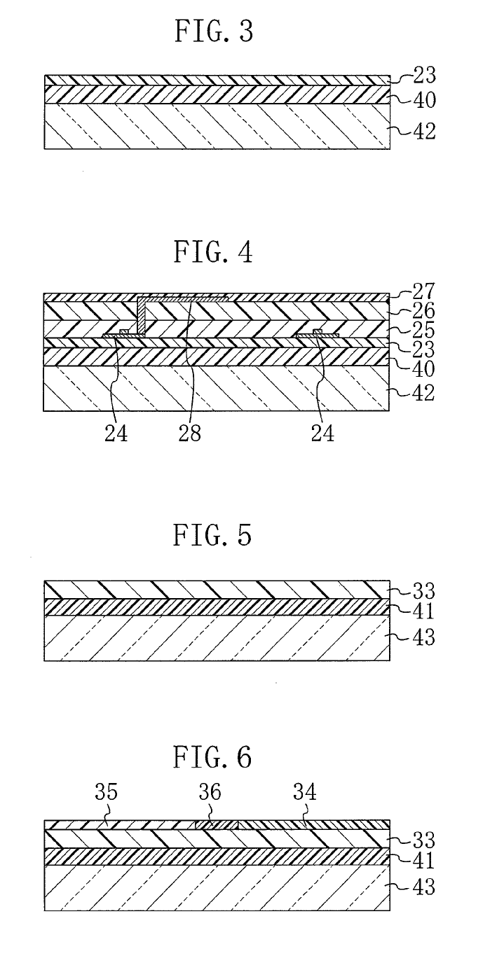

First, as illustrated in FIG. 3, a glass substrate 42 having a thickness of, e.g., approximately 0.7 mm is prepared as a support substrate.

Next, a sacrificial film 40 made of resin material having a heat-resistant temperature equal to or higher than 150° C., and a coefficient of thermal expansion equal to or less than 10 ppm/° C. is formed to a thickness of, e.g., approximately 1 μm on the glass substrate 42. As the resin material of the sacrificial film 40 satisfying such conditions, e.g., polyimide resin or fluorine epoxy resin can be used.

Then, an element-layer protective film 23 is formed of, e.g., SiO₂ to have a thickness of approximately 500 nm on the sacrificial film 40. The element-layer protective film 23 is for satisfactorily reducing etching of a display element layer when removing the sacrificial film 40.

Subsequently, as illustrated in FIG. 4, on the element-layer protective film 23, a metal film, a semiconductor film, a gate insulating film, etc. are formed, patterned, and so on, thereby forming TFTs 24.

Next, on the element-layer protective film 23 on which the TFTs 24 are formed, each of an interlayer insulating film 25 and a planarized film 26 is formed to a thickness of approximately 1-2 μm by using, e.g., a TEOS film or a SiN film.

Subsequently, contact holes are formed from a surface of the planarized film 26 to the TFTs 24, thereby forming metal interconnects 28 electrically connected to the TFTs 24. Transparent conductive films such as ITO film are formed and patterned on the surface of the planarized film 26, thereby also forming sub-pixel electrodes (not shown in the figure) in each sub-pixel.

Then, an alignment film 27 is formed on the planarized film 26 by using transparent resin.

Next, as illustrated in FIG. 5, a glass substrate 43 having a thickness of, e.g., approximately 0.7 mm is prepared as a support substrate separately from the above-described process.

Subsequently, a sacrificial film 41 made of resin material having a heat-resistant temperature equal to or higher than 150° C., and a coefficient of thermal expansion equal to or less than 10 ppm/° C. is formed to a thickness of, e.g., approximately 1 μm on the glass substrate 43. As the resin material of the sacrificial film 41 satisfying such conditions, e.g., polyimide resin or fluorine epoxy resin can be used.

Then, an element-layer protective film 33 is formed of, e.g., SiO₂, SiON, or SiNx to have a thickness of approximately 500 nm on the sacrificial film 41. The element-layer protective film 33 is for satisfactorily reducing etching of a color filter layer when removing the sacrificial film 41.

Subsequently, as illustrated in FIG. 6, a light blocking layer 36 are formed of metal such as Cr, or black resin on predetermined regions of the element-layer protective film 33.

Next, red, green, and blue color layers 34 and 35 are formed on the element-layer protective film 33 by using red light-sensitive resin, green light-sensitive resin, and blue light-sensitive resin.

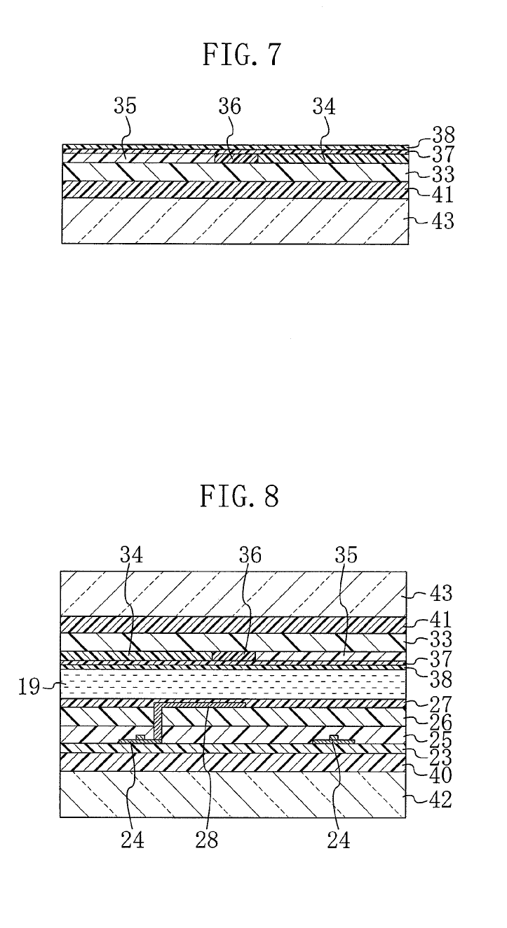

Then, as illustrated in FIG. 7, a transparent resin layer 37 having a thickness of, e.g., approximately 1-3 μm is formed on the color filter layer constituted by the color layers 34 and 35 by using, e.g., SiO₂.

Next, a common electrode 38 is formed on the transparent resin layer 37 by ITO sputtering, followed by forming a vertical alignment film on the common electrode 38.

Subsequently, as illustrated in FIG. 8, the substrate in FIG. 4 and the substrate in FIG. 7 are bonded together with element sides of such substrates facing each other. When bonding the substrates, the substrates are bonded to each other by frame-like sealing material with an opening, followed by injecting liquid crystal material between the substrates through the opening of the sealing material, which serves as a liquid crystal injection port.

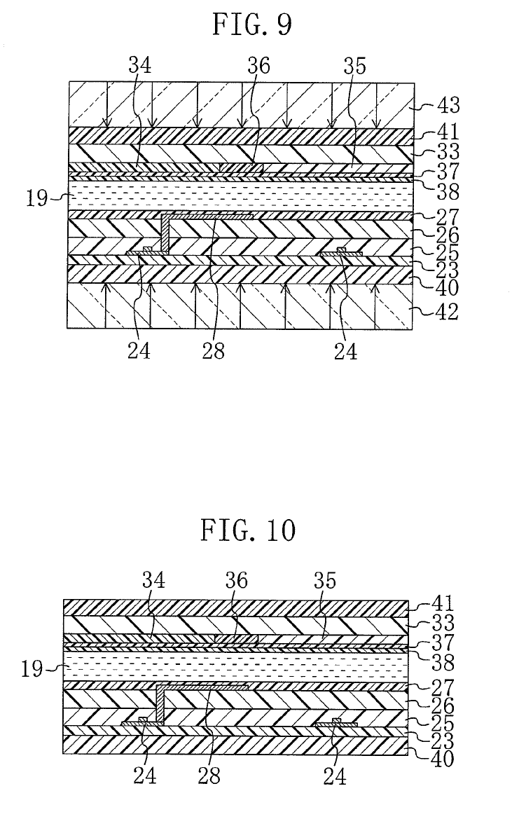

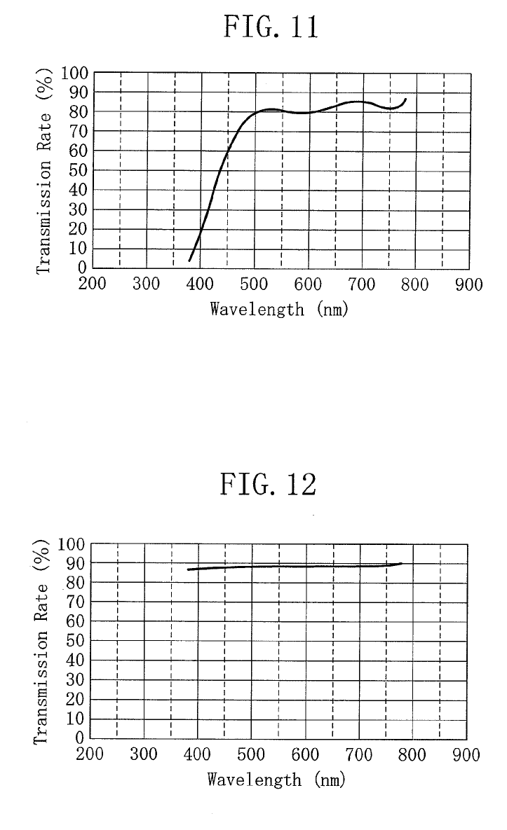

Then, as illustrated in FIG. 9, the bonded substrate is irradiated with laser light (indicated by arrows in FIG. 9) from the glass substrates 42 and 43 sides, thereby detaching the glass substrates 42 and 43 from the bonded substrate as illustrated in FIG. 10.

The removal of the glass substrates 42 and 43 may not be the detachment by the laser light irradiation. The glass substrates 42 and 43 may be removed by using, e.g., a polishing apparatus.

Next, the sacrificial films 40 and 41 exposed by removing the glass substrates 42 and 43 are removed by plasma etching.

The removal of the sacrificial films 40 and 41 is not limited to the removal by the plasma etching, and may be performed by microwave plasma etching.

Subsequently, on the element-layer protective films 23 and 33 exposed by removing the sacrificial films 40 and 41, the base layers 22 and 32 constituted by the transparent and colorless resin films as illustrated in FIG. 2 are formed to a thickness of, e.g., approximately 10 μm. At this point, the base layers 22 and 32 are, for example, formed of paraxylene resin by chemical vapor deposition (CVD) at room temperature (e.g., temperature equal to or lower than 50° C.).

Subsequently, a polarizing plate and a backlight unit (not shown in the figure) are provided on the TFT substrate 20 side, thereby obtaining the complete liquid crystal display apparatus 10.

Features and Advantages

Next, features and advantages of the first embodiment of the present invention will be described.

In a conventional technique in which laser light irradiation for phase transition from an amorphous silicon film to a polysilicon film, and for generation of hydrogen gas permits detachment of a first base material, it is difficult to completely eliminate adhesion in a first separation layer, and there is a possibility to cause partial detachment. Thus, it is difficult to prepare a device by using, in particular, a large-size substrate, and to prepare an extremely-thin device.

However, the liquid crystal display apparatus 10 of the first embodiment of the present invention uses the transparent and colorless resin films as the base layers 22 and 32, thereby obtaining good visibility and flexibility. In addition, the base layers 22 and 32 are formed by the vapor deposition at the room temperature, and therefore high-temperature heat is not applied to the display element layer when forming the base layers 22 and 23 on the display element layer. Thus, good display properties of the apparatus are obtained.

In addition, in the liquid crystal display apparatus 10, the TFT substrate 20 and the CF substrate 21 includes the base layers 22 and 32, respectively, resulting in better flexibility and display properties in the entire display apparatus.

Further, in the liquid crystal display apparatus 10, the transparent and colorless resin films used for the base layers 22 and 32 are made of, e.g., polyparaxylene resin. FIG. 11 illustrates a plot of light transmission rates (%) varying with wavelengths (nm) when transmitting light through a polyimide film (a thickness of 3.5 μm) which is typical resin conventionally used as the base layer. In addition, FIG. 12 illustrates a plot of light transmission rates (%) varying with wavelengths (nm) when transmitting light through a polyparaxylene resin (polyparaxylene film having a thickness of 10 μm) used for the base layers 22 and 32 of the present embodiment. As will be appreciated from the plot in FIG. 11, the base layer made of polyimide has the transmission rate which significantly drops when the wavelength becomes less than 500 nm, and the transmitted light is colored. On the other hand, as will be appreciated from the plot in FIG. 12, the base layers 22 and 32 made of polyparaxylene constantly has the transmission rate of approximately 90% even if the wavelength is changed. This allows the liquid crystal display apparatus 10 using the base layers 22 and 32 to have excellent display visibility.

Unlike the base layer constituted by, e.g., a polyimide film, which has undergone the heat application process, the base layers 22 and 32 of the TFT substrate 20 and the CF substrate 21 are made of, e.g., paraxylene resin in the liquid crystal display apparatus 10, thereby not causing inherent warpage after the heat application process. Further, better flexibility can be obtained, thereby smoothly rolling up the liquid crystal display apparatus 10. This ensures safety and space saving during storing and transporting the apparatus, and advantages are brought in production efficiency and cost.

In the manufacturing method of the liquid crystal display apparatus 10, the sacrificial films 40 and 41 made of resin material (polyimide resin) having the heat-resistant temperature equal to or higher than 150° C., and the coefficient of thermal expansion equal to or less than 10 ppm/° C. are first formed on the support substrates (glass substrates 42 and 43). This can maintain a good bonding state between the sacrificial film 40, 41 and the support substrate even if heat etc. is applied in the formation of the display element layer. The element-layer protective films 23 and 33 are formed on the sacrificial films 40 and 41 before the formation of the display element layer, thereby satisfactorily reducing removal of the display element layer when removing the sacrificial films 40 and 41 by etching etc. Further, the support substrates are detached from the sacrificial films 40 and 41 by the laser light irradiation, thereby easily and completely detaching the support substrates. The base layers 22 and 32 are formed on the element-layer protective films 23 and 33 from which the sacrificial films 40 and 41 are removed, by vapor-depositing, e.g., polyparaxylene resin thereon at the room temperature, thereby obtaining good display properties of the apparatus without applying high-temperature heat to the display elements. Further, the base layers 22 and 32 are formed by the vapor-deposition after the sacrificial films 40 and 41 are completely removed, thereby preparing an extremely-thin flexible device even with a large-size substrate.

In addition, the sacrificial films 40 and 41 are removed by the plasma etching, thereby easily removing the sacrificial films 40 and 41. Consequently, good production efficiency can be obtained. Further, the sacrificial films 40 and 41 are removed by the microwave plasma etching, thereby removing the sacrificial films 40 and 41 at low temperature, and having no effect of heat on the display elements. Consequently, better display properties of the apparatus can be obtained.

### Second Embodiment

Next, a liquid crystal display apparatus 50 of a second embodiment of the present invention will be described. In the liquid crystal display apparatus 50, the same reference numerals as those in the liquid crystal display apparatus 10 are used to represent equivalent elements, and the description thereof will not be repeated.

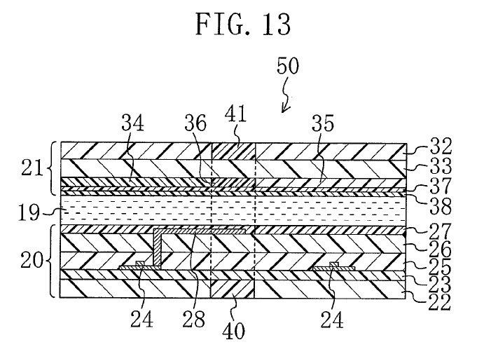

FIG. 13 schematically illustrates a cross section of the liquid crystal display apparatus 50. The liquid crystal display apparatus 50 differs from the liquid crystal display apparatus 10 of the first embodiment in that only regions of base layers 22 and 32 corresponding to a light blocking layer 36, i.e., a non-display region are replaced by sacrificial films 40 and 41. During a manufacturing process of the liquid crystal display apparatus 50, the sacrificial films 40 and 41 are not completely removed, and only the regions corresponding to the light blocking layer 36 (light blocking region) of a CF substrate 21, which divide a plurality of sub-pixel regions, are remained. The base layers 22 and 32 are formed in the remaining regions after the removal of the sacrificial films 40 and 41, thereby manufacturing the liquid crystal display apparatus 50.

According to such a structure, the remaining sacrificial films 40 and 41 allows better pressure resistance etc. as compared to the liquid crystal display apparatus with the base layers 22 and 32 being formed on the entire element-layer protective films 23 and 33. In addition, even if colored resin films are used as the sacrificial films 40 and 41, the sacrificial films 40 and 41 are formed only in the regions corresponding to the light blocking layer 36, thereby reducing adverse effects on image display.

### Third Embodiment

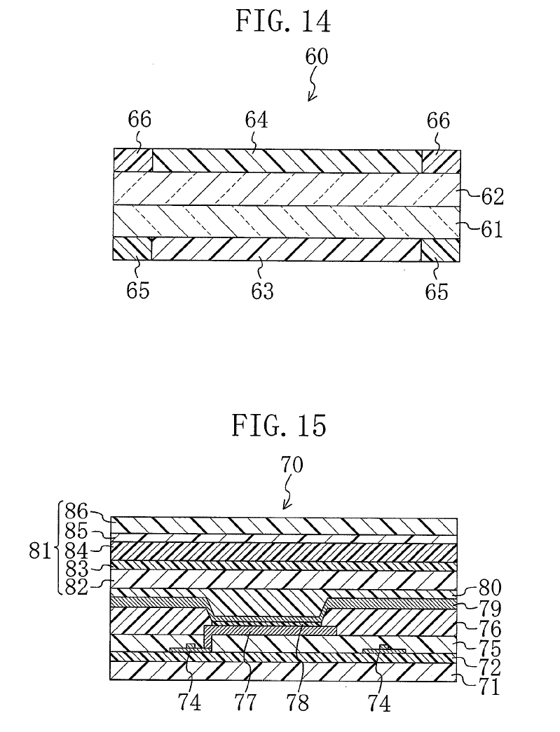

Next, a liquid crystal display apparatus 60 of a third embodiment of the present invention will be described. FIG. 14 is a cross-sectional view schematically illustrating the liquid crystal display apparatus 60. The liquid crystal display apparatus 60 includes a TFT substrate 61 and a CF substrate 62. Base layers 63 and 64 having the same structure as that of the base layers 22 and 32 of the liquid crystal display apparatus 10 and 50 are formed on surfaces of the TFT substrate 61 and the CF substrate 62. In the liquid crystal display apparatus 60, sacrificial films 65 and 66 are formed in regions corresponding to peripheral portions of the TFT substrate 61 and of the CF substrate 62, which serve as a non-display region (peripheral circuit region) instead of the base layers 63 and 64.

According to such a structure, the sacrificial films 65 and 66 are formed in the peripheral circuit regions, thereby forming a more-stable peripheral circuit. In addition, even if colored resin films are used as the sacrificial films 65 and 66, the sacrificial films 65 and 66 are formed only in the peripheral circuit regions, thereby reducing adverse effects on image display.

FIG. 14 illustrates the structure in which the peripheral circuit regions are provided in the TFT substrate 61 and the CF substrate 62. However, the present invention is not limited to such a structure, and a peripheral circuit region may be provided only on the TFT substrate 61 side, and the sacrificial film 65 corresponding to such a peripheral circuit region is provided only on the TFT substrate 61 side.

### Fourth Embodiment

### Structure of Organic EL Display Apparatus 70

FIG. 15 is a cross-sectional view schematically illustrating an organic EL display apparatus 70 of a fourth embodiment of the present invention.

The organic EL display apparatus 70 includes a base layer 71 constituted by a transparent and colorless resin film formed by vapor deposition at room temperature. As the transparent and colorless resin film constituting the base layer 71, e.g., paraxylene resin or acrylic resin can be used.

An element-layer protective film 72 is formed on the base layer 71. The element-layer protective film 72 is made of, e.g., SiO₂.

A display element layer including TFTs 74 etc. is formed on the element-layer protective film 72. The display element layer is constituted by the TFTs 74 formed on the element-layer protective film 72; an interlayer insulating film 75 such as a TEOS film or a SiN film provided so as to cover the TFTs 74; and metal interconnects penetrating through the interlayer insulating film 75 to be electrically connected to the TFTs 74. The metal interconnect further extends to above the interlayer insulating film 75 to serve as a first electrode 77. An insulating film 76 such as a TEOS film or a SiN film is formed on the interlayer insulating film 75.

The TFT 74 includes a semiconductor layer in which an active region is formed; a gate oxide film; a gate electrode; etc. The active region of the semiconductor layer is constituted by a channel region, and source and drain regions formed on both right and left sides of the channel region. The gate oxide film is formed on the channel region of the semiconductor layer. The gate electrode is formed on the gate oxide film.

The organic EL display apparatus 70 is a bottom-emission-type apparatus in which light is extracted from the first electrode 77 side. Thus, from the viewpoint of improving a light emission efficiency, it is preferred that the first electrode 77 is constituted by a thin film made of, e.g., ITO or SnO₂, which has a high work function and a high light transmission rate.

An organic EL layer 78 is formed on the first electrode 77. The organic EL layer 78 is constituted by a hole transport layer and a light emitting layer. The hole transport layer is not limited as long as the hole transport layer has a good hole injection efficiency. As material of the hole transport layer, organic material such as triphenylamine derivative, polyparaphenylene vinylene (PPV) derivative, and polyfluorene derivative can be used.

The light emitting layer includes, but not limited to, 8-hydroxyquinolinol derivative, thiazole derivative, and benzoxazole derivative. In addition, more than two types of these material may be combined, or additive agents such as dopant material may be added thereto.

The organic EL layer 78 has a two-layer structure of the hole transport layer and the light emitting layer, but is not limited to such a structure. That is, the organic EL layer 78 may have a single-layer structure constituted by only the light emitting layer. In addition, the organic EL layer 78 may be constituted by one or more of the hole transport layer, the hole injection layer, an electron injection layer, and an electron transport layer; and the light emitting layer.

A second electrode 79 is formed on the organic EL layer 78 and the insulating film 76. The second electrode 79 has a function to inject electrons to the organic EL layer 78. The second electrode 79 can be constituted by a thin film made of, e.g., Mg, Li, Ca, Ag, Al, In, Ce, or Cu, but is not limited to the above.

In the organic EL display apparatus 70, the first electrode 77 has a function to inject holes to the organic EL layer 78, and the second electrode 79 has the function to inject electrons to the organic EL layer 78. A mechanism to emit light from the organic EL layer 78 works by recombining the holes and the electrons injected from the first electrode 77 and the second electrode 79 in the organic EL layer 78. In addition, the base layer 71 and the first electrode 77 have light permeability, and the second electrode 79 has light reflectivity. The mechanism to extract light from the organic EL layer 78 works by transmitting light through the first electrode 77 and the base layer 71 (bottom emission system).

A planarized film 80 such as a TEOS film or a SiN film is formed on the second electrode 79.

A sealing film 81 constituted by a laminated body of resin films 82, 84, and 86 and inorganic films 83 and 85 is formed on the planarized film 80. Each of the resin films 82, 84, and 86 may be formed by using the same resin material as that of the base layer 71, or may be formed by using other resin material. The inorganic films 83 and 85 may be formed by using, e.g., SiNx, SiO₂, or Al₂O₃.

In addition, the sealing film 81 are not necessarily formed by laminating several resin and inorganic films as described above, or may be formed by laminating each one of resin and inorganic films. Further, the sealing film 81 may be formed by using a metal thin film.

(Manufacturing Method of Organic EL Display Apparatus 70)

Next, a method for manufacturing the organic EL display apparatus 70 of the embodiment of the present invention will be described. The manufacturing method described below is merely an example, and the organic EL display apparatus 70 of the present invention is not limited to the apparatus manufactured by the method described below.

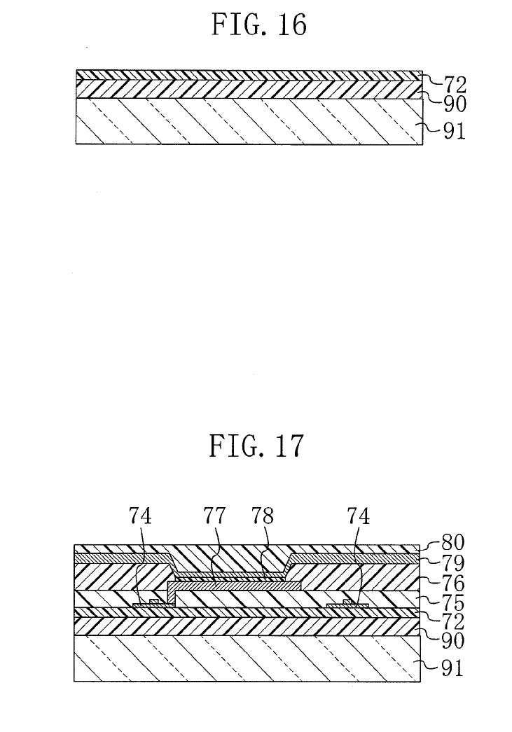

First, as illustrated in FIG. 16, a glass substrate 91 having a thickness of, e.g., approximately 0.7 mm is prepared as a support substrate.

Next, a sacrificial film 90 made of resin material having a heat-resistant temperature equal to or lower than 400° C., and a coefficient of thermal expansion equal to or less than 10 ppm/° C. is formed to a thickness of, e.g., approximately 1 μm on the glass substrate 91. As the resin material of the sacrificial film 90 satisfying such conditions, e.g., polyimide resin or fluorine epoxy resin can be used.

Then, an element-layer protective film 72 is formed of, e.g., SiO₂ to have a thickness of approximately 500 nm on the sacrificial film 90. The element-layer protective film 72 is for satisfactorily reducing etching of a display element layer when removing the sacrificial film 90.

Subsequently, as illustrated in FIG. 17, on the element-layer protective film 72, a metal film, a semiconductor film, etc. are formed, patterned, and so on, thereby forming TFTs 74.

Next, on the element-layer protective film 72 on which the TFTs 74 are formed, an interlayer insulating film 75 is formed to a thickness of approximately 1-2 μm by using, e.g., a TEOS film or a SiN film.

Subsequently, contact holes are formed from a surface of the interlayer insulating film 75 to the TFTs 74, thereby forming metal interconnects electrically connected to the TFTs 24 by using transparent conductive material such as ITO. A first electrode 77 having a thickness of, e.g., approximately 150 nm is formed by patterning etc.

Next, after an insulating film 76 having a thickness of, e.g., approximately 500 nm is formed on the interlayer insulating film 75, portions corresponding to the first electrodes 77 are removed by etching.

Then, a hole transport layer and a light emitting layer are formed on the first electrode 77, thereby forming an organic EL layer 78. As the hole transport layer, hole transport material coating made by dissolving or dispersing organic polymer material which is hole transport material in solvent is first supplied to the exposed first electrode 77 by, e.g., an ink-jet process. Then, a baking process is applied to form the hole transport layer. Next, as the light emitting layer, organic light emitting material coating made by dissolving or dispersing organic polymer material which is light emitting material in solvent is supplied so as to cover the hole transport layer by, e.g., the ink-jet process. Then, the baking process is applied to form the light emitting layer.

Subsequently, material such as Mg, Li, Ca, Ag, Al, In, Ce, or Cu is used to form a second electrode 79 on the insulating film 76 and the organic EL layer 78 by, e.g., sputtering. The thickness of the second electrode 79 is, e.g., approximately 150 nm.

Next, a TEOS film or a SiN film is formed on the second electrode 79, and then a surface thereof is polished by, e.g., chemical mechanical polishing (CMP) to form a planarized film 80.

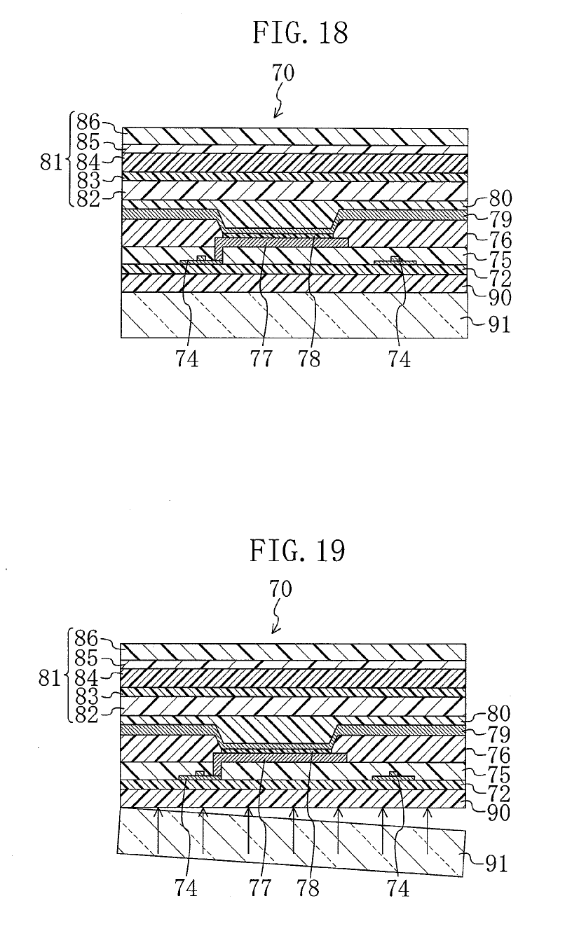

Then, as illustrated in FIG. 18, a resin film 82, an inorganic film 83, a resin film 84, an inorganic film 85, and a resin film 86 are formed on the planarized film 80 in order presented above, thereby forming a sealing film 81. The resin films 82, 84, and 86 are formed to a thickness of approximately 10 μm by using, e.g., paraxylene resin. In addition, the inorganic films 83 and 85 are formed to a thickness of approximately 500 nm by using, e.g., SiNx, SiO₂, or Al₂O₃.

Subsequently, as illustrated in FIG. 19, the glass substrate 91 is irradiated with laser light (indicated by arrows in FIG. 19) from the glass substrate 91 side, thereby detaching the glass substrate 91.

At this point, the removal of the glass substrate 91 is not necessarily the detachment by the laser light irradiation. The glass substrate 91 may be removed by using, e.g., polishing and etching apparatuses.

Next, the sacrificial film 90 exposed by removing the glass substrate 91 is removed by plasma etching. At this point, the sacrificial film 90 is not necessarily removed by the plasma etching, and may be removed by, e.g., microwave plasma etching.

Subsequently, on the element-layer protective film 72 exposed by removing the sacrificial film 90, the base layer 71 constituted by the transparent and colorless resin film as illustrated in FIG. 15 is formed to a thickness of, e.g., approximately 10 μm. The base layer 71 is, for example, formed of polyparaxylene resin by chemical vapor deposition (CVD) at room temperature (e.g., temperature equal to or lower than 50° C.). As described above, the complete organic EL display apparatus 70 can be obtained.

### Fifth Embodiment

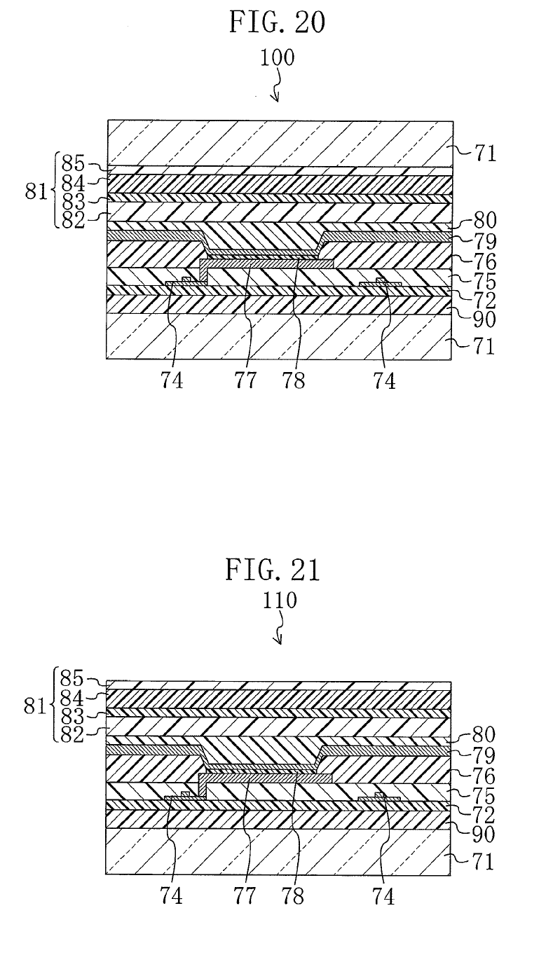

FIGS. 20-22 illustrate a fifth embodiment of the present invention.

FIG. 20 is a cross-sectional view schematically illustrating an organic EL display apparatus 100. The organic EL display apparatus 100 differs from the organic EL display apparatus 70 of the fourth embodiment in that base layers 71 having the maximum thickness among constituting layers of the apparatus illustrated in FIG. 20 are formed as undermost and uppermost layers.

FIG. 21 is a cross-sectional view schematically illustrating an organic EL display apparatus 110. The organic EL display apparatus 110 differs from the organic EL display apparatus 100 in that a base layer 71 having the maximum thickness among the apparatus-constituting layers is formed as an undermost layer.

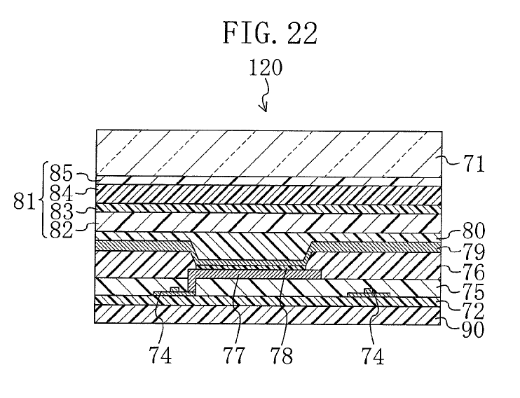

FIG. 22 is a cross-sectional view schematically illustrating an organic EL display apparatus 120. The organic EL display apparatus 120 differs from the organic EL display apparatus 100 in that a base layer 71 having the maximum thickness among the apparatus-constituting layers is formed as an uppermost layer.

As described above, in the organic EL display apparatuses 100, 110, and 120, the degree of curvature, warpage, curl, etc. is controlled by the base layer 71 having the maximum thickness among the apparatus-constituting layers. Thus, warpage, curvature, etc. of the device itself formed in the apparatus can be satisfactorily reduced, thereby obtaining better quality of the display apparatus.

The structure in which the degree of apparatus curvature, warpage, etc. is controlled by the base layer having the maximum thickness is not limited to the organic EL display apparatus, and may be used in the liquid crystal display apparatus described in the embodiments of the present invention.

Features and Advantages

Next, features and advantages of the fourth embodiment of the present invention will be described.

The organic EL display apparatus 70 of the fourth embodiment of the present invention uses the transparent and colorless resin film as the base layer 71, thereby obtaining good visibility and flexibility. In addition, the base layer 71 is formed by the vapor-deposition at the room temperature, thereby not applying high-temperature heat to the display element layer when forming the base layer 71 on the display element layer. Thus, good display properties of the apparatus can be obtained.

In addition, the organic EL display apparatus 70 also includes the base layer 71 in the sealing film 81, thereby obtaining better flexibility and display properties in the entire display apparatus.

Further, in the organic EL display apparatus 70, the transparent and colorless resin film used for the base layer 71 is made of, e.g., paraxylene resin, thereby obtaining excellent display visibility. In addition, unlike typical base layers made of, e.g., polyimide film, the base layer 71 is made of, e.g., polyparaxylene resin, thereby not causing inherent warpage. Further, better flexibility can be obtained, thereby smoothly rolling up the organic EL display apparatus 70. This ensures safety and space saving during storing and transporting the apparatus, and advantages are brought in production efficiency and cost.

In the manufacturing method of the organic EL display apparatus 70, the sacrificial film 90 made of resin material (polyimide resin) having the heat-resistant temperature equal to or higher than 150° C., and the coefficient of thermal expansion equal to or less than 10 ppm/° C. is first formed on the support substrate (glass substrate 91). This can maintain a good bonding state between the sacrificial film 90 and the support substrate even if heat etc. are applied in the formation of the display element layer. The element-layer protective film 72 is formed on the sacrificial film 90 before the formation of the display element layer, thereby satisfactorily reducing removal of the display element layer when removing the sacrificial film 90 by etching etc. Further, the support substrate is detached from the sacrificial film 90 by the laser light irradiation, thereby easily and completely detaching the support substrate. The base layer 71 is formed on the element-layer protective film 72 from which the sacrificial film 90 is removed, by vapor-depositing, e.g., paraxylene resin thereon at the room temperature, thereby obtaining good display properties of the apparatus without applying high-temperature heat to the display elements. Further, the base layer 71 is formed by the vapor-deposition after the sacrificial film 90 is completely removed, thereby preparing an extremely-thin flexible device even with a large-size substrate.

In addition, the sacrificial film 90 is removed by the plasma etching, thereby easily removing the sacrificial film 90. Consequently, good production efficiency can be obtained. Further, the sacrificial film 90 is removed by the microwave plasma etching, thereby removing the sacrificial film 90 at low temperature, and having no effect of heat on the display elements. Consequently, better display properties of the apparatus can be obtained.

In the first to fourth embodiments, the liquid crystal display (LCD) apparatuses and the organic electro luminescence (organic EL) display apparatuses have been described as display apparatuses. However, display apparatuses may include electrophoretic display apparatuses; plasma display (PD) apparatuses; plasma addressed liquid crystal (PALC) display apparatuses; inorganic electro luminescence (inorganic EL) display apparatuses; field emission display (FED) apparatuses; and surface-conduction electron-emitter display (SED) apparatuses.

### INDUSTRIAL APPLICABILITY

As described above, the present invention is useful for the display apparatus, the thin-film substrate, and the method for manufacturing the display apparatus.

1. A display apparatus, comprising:
a first substrate including a base layer, and a display element layer formed on the base layer,
wherein the base layer of the first substrate is constituted by a transparent and colorless resin film formed by vapor deposition at room temperature.

2. The display apparatus of claim 1, further comprising:
a second substrate including a base layer provided so as to face the first substrate, and constituted by a transparent and colorless resin film, and a display element layer formed on the base layer.

3. The display apparatus of claim 1, wherein
a sacrificial film made of resin material having a heat-resistant temperature equal to or higher than 150° C., and a coefficient of thermal expansion equal to or less than 10 ppm/° C. is formed corresponding to a non-display region of the display element layer between the display element layer and the base layer.

4. The display apparatus of claim 3, wherein
the display element layer includes a plurality of sub-pixel regions, and a light blocking region provided so as to divide the sub-pixel regions; and
a non-display region of the display element layer corresponding to the sacrificial film are the light blocking region.

5. The display apparatus of claim 3, wherein
the display element layer includes a peripheral circuit region; and
a non-display region of the display element layer corresponding to the sacrificial film is the peripheral circuit region.

6. The display apparatus of claim 3, wherein
the sacrificial film is made of polyimide resin.

7. The display apparatus of claim 1, wherein
the transparent and colorless resin film is made of polyparaxylene resin.

8. The display apparatus of claim 1, further comprising:
an element-layer protective film is formed between the base layer and the display element layer.

9. The display apparatus of claim 1, wherein
the base layer is formed to have a thickness in which curvature or warpage of the display apparatus can be controlled.

10. A liquid crystal display apparatus, comprising:
a TFT substrate including a base layer which is constituted by a transparent and colorless resin film formed by vapor deposition at room temperature, and a display element layer with TFTs formed on the base layer; and
a CF substrate including a base layer which faces the TFT substrate with liquid crystal material being interposed therebetween, and which is constituted by a transparent and colorless resin film formed by vapor deposition at room temperature, and a display element layer with a color filter formed on the base layer.

11. A bottom-emission-type organic EL display apparatus, comprising:
a base layer constituted by a transparent and colorless resin film formed by vapor deposition at room temperature;
first electrodes formed on the base layer;
organic EL layers formed on the first electrodes; and
a second electrode formed on the organic EL layers.

12. The organic EL display apparatus of claim 11, further comprising:
a sealing film which is formed on the second electrode, and which is constituted by a laminated body of resin films and inorganic films.

13. A thin-film substrate, comprising:
a base layer constituted by a transparent and colorless resin film formed by vapor deposition at room temperature; and
a display element layer formed on the base layer.

14. A method for manufacturing a display apparatus, comprising:
a first step for preparing a support substrate on which a sacrificial film made of resin material having a heat-resistant temperature equal to or higher than 150° C., and a coefficient of thermal expansion equal to or less than 10 ppm/° C. is formed;
a second step for forming an element-layer protective film on the sacrificial film;
a third step for forming a display element layer on the element-layer protective film;
a fourth step for removing the support substrate from the sacrificial film;
a fifth step for removing the sacrificial film from the element-layer protective film; and
a sixth step for forming a base layer by vapor-depositing a transparent and colorless resin film on the element-layer protective film from which the sacrificial film is removed, at room temperature.

15. The method of claim 14, further comprising:
a bonded substrate forming step at which the first to third steps are repeated to form two support substrates on which the display element layers are formed, followed by bonding the substrates with the display element layers facing each other,
wherein the support substrates are removed from the sacrificial films of the bonded substrate at the fourth step;
the sacrificial films are removed from the element-layer protective films of the bonded substrate at the fifth step; and
base layers are formed by vapor-depositing transparent and colorless resin films on the protective films from which the sacrificial films are removed, at room temperature at the sixth step.

16. The method of claim 14, wherein,
at the fifth step, the sacrificial film corresponding to the non-display region of the display element layer is remained, and the sacrificial film corresponding to other regions is removed.

17. The method of claim 16, wherein
the display element layer includes a plurality of sub-pixel regions, and a light blocking region provided so as to divide the sub-pixel regions; and
the non-display region of the display element layer corresponding to the remaining sacrificial film are the light blocking region.

18. The method of claim 16, wherein
the display element layer includes a peripheral circuit region; and
the non-display region of the display element layer corresponding to the remaining sacrificial film is the peripheral circuit region.

19. The method of claim 14, wherein,
at the fifth step, the sacrificial film is removed by plasma etching.

20. The method of claim 14, wherein,
at the fifth step, the sacrificial film is removed by microwave plasma etching.

21. The method of claim 14, wherein
the sacrificial film is made of polyimide resin.

22. The method of claim 14, wherein
the transparent and colorless resin film is made of polyparaxylene resin.

23. The method of claim 14, wherein,
at the fourth step, the support substrate is detached and removed from the sacrificial film by laser light irradiation.
